(19) United States
(12) Patent Application Publication
(10) Pub. No.: US 2014/0011355 A1
(43) Pub. Date: Jan. 9, 2014

(54) Method of Making Metal/Semiconductor Compound Thin Film

(71) Applicants: Dongping Wu, Shanghai (CN); Zhiwei Zhu, Shanghai (CN); Shili Zhang, Stockholm (SE); Wei Zhang, Shanghai (CN)

(72) Inventors: Dongping Wu, Shanghai (CN); Zhiwei Zhu, Shanghai (CN); Shili Zhang, Stockholm (SE); Wei Zhang, Shanghai (CN)

(73) Assignee: FUDAN UNIVERSITY, Shanghai (CN)

(21) Appl. No.: 13/391,623

(22) PCT Filed: Sep. 28, 2011
(86) PCT No.: PCT/CN11/80264

§ 371 Date: Feb. 21, 2012

(30) Foreign Application Priority Data
Mar. 17, 2011 (CN) 201110063760.3

(51) Int. Cl. H01L 21/285

(52) U.S. Cl. CPC H01L 21/28518
USPC 438/664

(57) ABSTRACT

The present disclosure provides a method of making metal/semiconductor compound thin films, in which a target material is partially ionized into an ionic state during metal deposition using a PVD process, so as to produce metal ions, and in which a substrate bias voltage is applied to a semiconductor substrate, causing the metal ions to accelerate into the semiconductor substrate and enter the semiconductor substrate, resulting in more metal ions diffusing to the surface of the semiconductor substrate, greater deposition depth, and increased thickness of the eventually formed metal/semiconductor compound thin film. An amount of metal ions entering the semiconductor substrate can be adjusted by adjusting the substrate bias voltage, so as to adjust the thickness of the eventually formed metal/semiconductor compound.

### FIELD

The present disclosure is related to microelectronic device technologies, and particularly to a method of fabricating metal/semiconductor compound thin films.

### BACKGROUND

Metal/semiconductor compound thin films have been widely used as metal electrodes to form metal-semiconductor contacts with silicon, germanium or silicon-germanium semiconductors for the source/drain and gate of metal-oxide-semiconductor field effect transistors (MOSFET).

From serving as reliable contacts for simple diodes in the beginning to using self-aligned metal/semiconductor compound thin film (salicide) forming processes to form low-resistance source/drain contacts and low-sheet-resistance gate electrodes in MOSFETs nowadays, metal/semiconductor compound thin films have played very important roles in the miniaturization of CMOS device sizes and the enhancement of device properties. As semiconductor fabrication technologies continue to improve, metal/semiconductor compound thin films have evolved from the earlier titanium silicide (TiSi₂), cobalt silicide (CoSi₂) to today's main stream nickel silicide (NiSi) or platinum incorporated nickel silicide (Ni(Pi)Si.

Also, as device sizes continue to shrink, the thickness of the metal/semiconductor compound thin films is required to be thinner and thinner. Conventional processes of forming the Metal/semiconductor compound thin films, such as titanium silicide processes, cobalt silicide processes, nickel silicide processes, etc., are not suitable for forming ultra-thin metal/semiconductor compound thin films.

Patent application entitled “Method of forming ultra-thin and controllable metal silicides” (Chinese Patent Application Publication Number CN101764058A) disclosed a method of making metal silicides, which forms a metal silicide on the surface of a silicon substrate by depositing a metal layer on the silicon substrate, removing the remaining metal on the silicon substrate after the metal layer having diffused into the silicon substrate, and annealing. Because the diffusion of metal into the silicon substrate can reach diffusion saturation, the amount of diffused metal is limited and fixed. Therefore, the thickness of the metal silicide made using this method is very thin (typically about 3-4 nm), and this thickness is controllable.

Usually, the metal layer is formed using physical vapor deposition (PVD), and during the metal deposition, metal particles produced by collisions are not ionized, and the silicon substrate is also not biased.

The above method, however, has the following shortcomings: because the amount of metal diffused into the silicon substrate under room temperature is limited, the method cannot be used to make thicker metal silicide films. The metal silicide films required for the fabrication of some integrated circuits, however, are thicker than the metal silicide films that can be made using the above method.

Therefore, there is a need for an improved method of fabricating metal/semiconductor compound thin films.

### SUMMARY

A purpose of the present invention is to provide a method of fabricating metal/semiconductor compound thin films, so as to obtain a metal/semiconuctor compound ultra-thin film of an appropriate thickness.

To solve the above problems, the present disclosure provides a method of fabricating a metal/semiconductor compound thin film, the method comprising:

providing a semiconductor substrate;
depositing a metal layer on the semiconductor substrate using a PVD process, the metal layer having metal diffusing into the semiconductor substrate; wherein during the PVD process, a target material is partially ionized into an ionic state so as to produce metal ions, and a bias voltage is applied to the semiconductor substrate;
removing a remaining part of the metal layer from a surface of the semiconductor substrate; and
performing annealing on the semiconductor substrate, thereby forming the metal/semiconductor compound thin film on the surface of the semiconductor substrate.

In one embodiment, the metal/semiconductor compound thin film has a thickness of 3-11 nm.

In one embodiment, the target material is partially ionized into an ionic state by applying a first bias voltage to the target material.

In one embodiment, the first bias voltage is any one of a direct current (DC) bias voltage, an alternating current (AC) bias voltage, and a pulsed bias voltage.

In one embodiment, the bias voltage applied to the semiconductor substrate is any one of a direct current (DC) bias voltage, an alternating current (AC) bias voltage, and a pulsed bias voltage.

In one embodiment, the semiconductor substrate is silicon or silicon-on-insulator, and the metal/semiconductor compound thin film includes a metal silicide.

In one embodiment, the semiconductor substrate is germanium or germanium-on-insulator, and the metal/semiconductor compound thin film includes a metal germanide.

In one embodiment, the metal/semiconductor compound thin film is formed by metal reacting with the semiconductor substrate, where the metal can be any of nickel, cobalt, titanium, and ytterbium, or any of nickel, cobalt, titanium, and ytterbium with platinum incorporation.

In one embodiment, the metal is also incorporated with tungsten and/or molybdenum.

In one embodiment, the substrate is at a temperature of 0˜300° C. when the metal layer is deposited on the semiconductor substrate.

In one embodiment, the annealing is performed at a temperature of 200˜900° C.

Using the above technics, the present invention has the following advantages and positive effects, as compared with conventional technologies:

1) In the method for making a metal/semiconductor compound thin film, as provided by the present disclosure, the target material in the PVD process for depositing metal is partially ionized into an ionic state, so as to produce metal ions, and a substrate bias voltage is applied to the semiconductor substrate, causing the metal ions to accelerate into the semiconductor substrate. The ions enter the semiconductor substrate, resulting in more metal ions diffusing into a surface of the semiconductor substrate, greater deposition depth, and increased thickness of the eventually formed metal/semiconductor compound thin film.
2) In the method for making a metal/semiconductor compound thin film, as provided by the present disclosure, an amount of metal ions entering the semiconductor substrate can be adjusted by adjusting the substrate bias voltage. Thus, a thickness of the eventually formed metal/semiconductor compound thin film is also adjustable.

### BRIEF DESCRIPTION OF THE DRAWINGS

FIG. 1 is a flowchart illustrating a method of making a metal/semiconductor compound thin film, as provided by an embodiment of the present invention.

FIGS. 2A to 2C are device cross-sectional diagrams corresponding to process steps of the method of making the metal/semiconductor compound thin film, as provided by an embodiment of the present invention.

### DESCRIPTION OF EMBODIMENTS

A method of making a metal/semiconductor compound thin film, as provided by the present disclosure, is explained in further detail with respect to the drawings and specific embodiments. The advantages and characteristics of the present invention will be more clearly demonstrated based on the following discussion and the claims. It should be noted that, the drawings use simplified forms and inaccurate proportions and are to be used only to assist in suitably and clearly explain certain embodiments of the present invention.

As a key idea in the present disclosure, a method for making a metal/semiconductor compound thin film is provided, wherein a target material in a PVD process for depositing metal is partially ionized into an ionic state, thereby producing metal ions, and wherein a substrate bias voltage is applied to the semiconductor substrate, causing the metal ions to accelerate into the semiconductor substrate. The ions enter the semiconductor substrate, resulting in more metal ions diffusing into a surface of the semiconductor substrate, greater deposition depth, and increased thickness of the eventually formed metal/semiconductor compound thin film. At the same time, an amount of metal ions entering into the semiconductor substrate can be adjusted by adjusting the substrate bias voltage, so that a thickness of the eventually formed metal/semiconductor compound thin film can be adjusted.

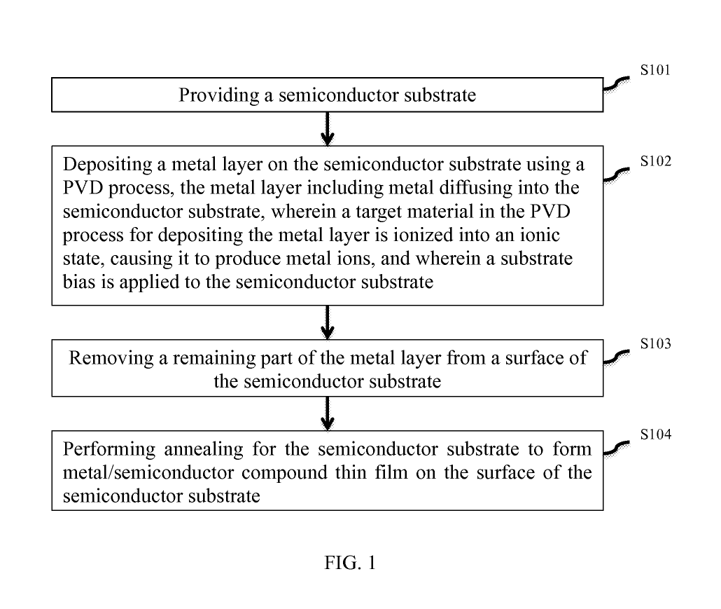

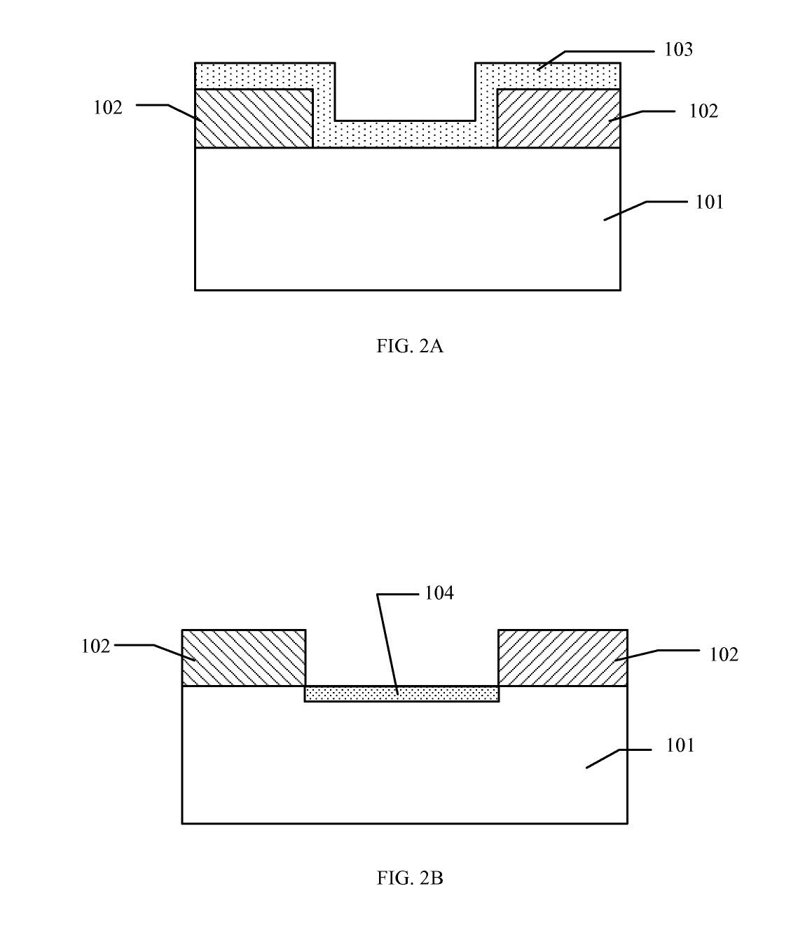

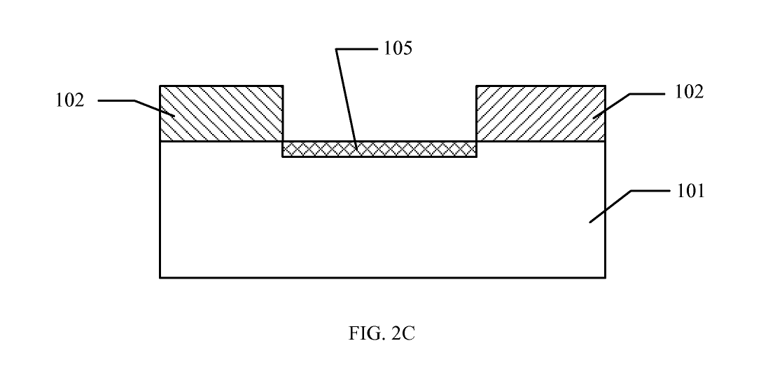

Reference is now made to FIG. 1, and FIGS. 2A to 2C. FIG. 1 is a flowchart illustrating a method of making a metal/semiconductor compound thin film, as provided by an embodiment of the present invention. FIGS. 2A to 2C are device cross-sectional diagrams corresponding to process steps of the method of making the metal/semiconductor compound thin film, as provided by an embodiment of the present invention. As shown in FIG. 1, and FIGS. 2A to 2C, the method of making a metal/semiconductor compound thin film, as provided by an embodiment of the present invention, comprises the following steps.

Specifically, a semiconductor substrate 101 is prepared and goes through various processes before film growth, such as cleaning and removing a native oxide film on the semiconductor substrate, etc. Also, a diffusion barrier layer 102 can be formed to selectively cover the semiconductor substrate. The diffusion barrier layer 102 can be silicon dioxide, silicon nitride or other insulating dielectric layer.

In step 102, a metal layer 103 is deposited on the semiconductor substrate 101 by PVD, as shown in FIG. 2A. The metal in the metal layer 103 diffuses into the semiconductor substrate 101. During the deposition of the metal layer 103 by PVD, a target material is partially ionized into an ionic state, causing it to produce metal ions, and a substrate bias voltage is applied to the semiconductor substrate 101.

In step 103, the metal layer 103 remaining on the surface of the semiconductor substrate 101 is removed. Specifically, wet etching or dry etching can be used to remove the metal layer 101 remaining on the semiconductor substrate 101. The device cross-sectional diagram after removing the metal layer 103 remaining on the surface of the semiconductor substrate 101 is shown in FIG. 2B. After the metal diffuse into the surface of the semiconductor substrate 101, a metal-containing semiconductor thin film 104 is formed on the surface of the semiconductor substrate 101.

In step 104, the semiconductor substrate 101 goes through annealing, and a metal-semiconductor compound thin film 105 is thereby formed on the surface of the semiconductor substrate 101.

In a further embodiment, the metal/semiconductor compound thin film has a thickness of 3-11 nm.

In a further embodiment, the target material is partially ionized into an ionic state by applying a first bias voltage to the target material. Understandably, the present invention is not limited to this approach, and any approaches to ionize the target material to an ionic state are also included in the scope of protection for the present invention.

In a further embodiment, the first bias voltage is any of a direct current (DC) bias voltage, an alternating current (AC) bias voltage, and a pulsed bias voltage.

Note that a value of the first bias voltage depends on the PVD system used, i.e., the value of the first bias voltage may change accordingly for different PVD systems. Generally speaking, the first bias voltage can be 200V-1000V, which is a root-mean-square (RMS) value an AC bias voltage or a pulsed bias voltage. Furthermore, the substrate bias voltage can be any of a DC bias voltage, an AC bias voltage, and a pulsed bias voltage.

Note that the substrate bias is adjustable. By adjusting a value of the substrate bias voltage, a number of metal ions diffused into the surface of the semiconductor substrate can be adjusted, so that a thickness of the eventually formed metal/semiconductor compound thin film can also be adjustable. Generally speaking, the substrate bias voltage can be 200V-1000V, which is a root-mean-square (RMS) value an AC vias voltage or a pulsed bias voltage.

In a further embodiment, the semiconductor substrate 101 is silicon or silicon-on-insulator, and the metal/semiconductor compound thin film includes a metal silicide.

In a further embodiment, the semiconductor substrate 101 is germanium or germanium-on-insulator, and the metal/semiconductor compound thin film includes a metal germanide.

Note that when the semiconductor substrate 101 is silicon or germanium, the substrate bias voltage can be any of a DC bias voltage, an AC bias voltage, and a pulsed bias voltage; when the semiconductor substrate 101 is silicon-on-insulator or germanium-on-insulator, a DC bias voltage would not work and either an AC bias voltage or a pulsed bias voltage is needed because the substrate includes an insulator layer.

Understandably, the semiconductor substrate 101 is not limited to the kinds of substrate in the above examples. Other kinds of semiconductor substrates, such as III-V compound semiconductor substrates, etc., are also included in the scope of protection for the claimed invention.

In a further embodiment, the metal/semiconductor compound thin film 105 is formed from metal reacting with the semiconductor substrate 101. The metal can be any of nickel, cobalt, titanium, and ytterbium, or any of nickel, cobalt, titanium, and ytterbium with platinum incorporation. The reason for platinum incorporation is because pure nickel silicide has poor stability under high temperature, or tends to show non-uniformity in thickness and agglomeration, or forms nickel di-silicide (NiSi₂) having high resistivity, seriously affecting the device properties. Thus, in order to slow the growth of nickel silicide so as to prevent the nickel silicide film from agglomeration or forming nickel di-silicide, platinum can be incorporated into nickel with a specific ratio. The incorporation of platinum into other metals is similarly explained.

In a further embodiment, the metal is further incorporated with tungsten and/or molybdenum, in order to further control the growth of nickel silicide or platinum incorporated nickel silicide and the diffusion of nickel and platinum, and to increase the stability of the nickel silicide or platinum incorporated nickel silicide. The incorporation of tungsten and/or molybdenum into other metals is similarly explained.

Understandably, the metal in the present invention is not limited to the specific metals in the above examples, other metals capable of reacting with semiconductor materials to form metal/semiconductor compound thin films are all included in the scope of protection for the present invention.

In a further embodiment, a substrate temperature during the deposition of the metal layer on the semiconductor substrate is 0˜300° C., because for nickel, a deposition temperature exceeding 300° C. can result in excessive nickel diffusion and nickel reacting directly with silicon to form nickel silicide, leading to loss of control of film thickness. Under the specific temperature, nickel would diffuse into the semiconductor substrate via the silicon surface, and such diffusion has the characteristics of self-saturation, that is, the diffusion of nickel into the semiconductor substrate only happens in a thin surface layer of the silicon, forming a thin nickel layer of a certain silicon/nickel ratio. A thickness of the thin nickel layer is related to the substrate temperature during deposition. The higher the temperature, the thicker the thin nickel layer. At room temperature, an equivalent nickel thickness of the thin nickel layer is about 2 nanometers.

In a further embodiment, the annealing temperature is 200˜900° C.

In summary, the present disclosure provides a method of making a metal/semiconductor compound thin film. In the method, a target material is partially ionized into an ionic state during metal deposition using a PVD process, causing it to produce metal ions, and a substrate bias voltage is applied to a semiconductor substrate, causing the metal ions to accelerate toward the semiconductor substrate and enter the semiconductor substrate, resulting in more metal ions diffusing into the surface of the semiconductor substrate, greater deposition depth, and increased thickness of the eventually formed metal/semiconductor compound thin film. At the same time, an amount of metal ions entering into the semiconductor substrate can be adjusted by adjusting the substrate bias voltage, so that the thickness of the eventually formed metal/semiconductor compound thin film can be adjusted.

Apparently, without departing from the spirit and scope of the present invention, those skilled in the art can make various changes and modifications to the present disclosure. Therefore, if such changes and modifications are within the scope of the claims and their equivalents, the present invention intends to include such changes and modifications.

1. A method of making a metal/semiconductor compound thin film, characterized in that the method comprises:
providing a semiconductor substrate;
depositing a metal layer on the semiconductor substrate using a PVD process, the metal layer including metal diffusing into the semiconductor substrate, wherein a target material in the PVD process for depositing the metal layer is ionized into an ionic state, causing it to produce metal ions, and wherein a substrate bias is applied to the semiconductor substrate;
removing a remaining part of the metal layer from a surface of the semiconductor substrate, and
performing annealing for the semiconductor substrate to form metal/semiconductor compound thin film on the surface of the semiconductor substrate.

2. The method of making the metal/semiconductor compound thin film according to claim 1, further characterized in that the metal/semiconductor compound thin film has a thickness of 3-11 nm.

3. The method of making the metal/semiconductor compound thin film according to claim 2, further characterized in that the target material is partially ionized into an ionic state by applying a first bias voltage to the target material.

4. The method of making the metal/semiconductor compound thin film according to claim 3, further characterized in that the first bias voltage is any one of a direct current (DC) bias voltage, an alternating current (AC) bias voltage, and a pulsed bias voltage

5. The method of making the metal/semiconductor compound thin film according to claim 2, further characterized in that the substrate bias voltage is any one of a direct current (DC) bias voltage, an alternating current (AC) bias voltage, and a pulsed bias voltage.

6. The method of making the metal/semiconductor compound thin film according to claim 1, further characterized in that the semiconductor substrate is silicon or silicon-on-insulator, and the metal/semiconductor compound thin film includes a metal silicide.

7. The method of making the metal/semiconductor compound thin film according to claim 1, further characterized in that the semiconductor substrate is germanium or germanium on oxide, and the metal/semiconductor compound thin film includes a metal germanide.

8. The method of making the metal/semiconductor compound thin film according to claim 1, further characterized in that the metal/semiconductor compound thin film is formed by the metal reacting with the semiconductor substrate, where the metal can be any of nickel, cobalt, titanium, ytterbium, nickel with platinum incorporation, cobalt with platinum incorporation, titanium with platinum incorporation, and ytterbium with platinum incorporation.

9. The method of making the metal/semiconductor compound thin film according to claim 8, further characterized in that the metal is also incorporated with tungsten and/or molybdenum.

10. The method of making the metal/semiconductor compound thin film according to claim 1, further characterized in that the substrate is at a temperature of 0˜300° C. when the metal layer is deposited on the semiconductor substrate.

11. The method of making the metal/semiconductor compound thin film according to claim 1, further characterized in that the annealing is performed at a temperature of 200˜900° C.
